(19) United States
(12) Patent Application Publication
(10) Pub. No.: US 2026/0154211 A1
(43) Pub. Date: Jun. 4, 2026

(54) MEMORY DEVICE FOR INPUTTING AND OUTPUTTING DATA BY SHARING A PLURALITY OF CHANNELS

(71) Applicant: SK hynix Inc., Icheon-si Gyeonggi-do (KR)

(72) Inventor: Choung Ki SONG, Icheon-si Gyeonggi-do (KR)

(73) Assignee: SK hynix Inc., Icheon-si Gyeonggi-do (KR)

(21) Appl. No.: 19/178,296

(22) Filed: Apr. 14, 2025

(30) Foreign Application Priority Data
Nov. 29, 2024 (KR) 10-2024-0175953

(51) Int. Cl. G06F 13/16; G06F 11/10; G06F 13/40

(52) U.S. Cl. CPC G06F 13/1678; G06F 11/1048; G06F 13/1689; G06F 13/4068

(57) ABSTRACT

A memory device includes a first core die including first to N-th channels and a second core die including (N+1)-th to 2N-th channels. A channel among the first to N-th channels of the first core die and a channel among the (N+1)-th to 2N-th channels of the second core die input and output data by receiving a write command in common and a read command in common.

### CROSS-REFERENCE TO RELATED APPLICATION

The present application claims priority under 35 U.S.C. § 119(a) to Korean Patent Application No. 10-2024-0175953, filed in the Korean Intellectual Property Office on Nov. 29, 2024, the entire contents of which application is incorporated herein by reference.

### BACKGROUND

Various embodiments of the present disclosure relate to a memory device for inputting and outputting data using a wide bandwidth in a way that at least two of a plurality of channels included in core dies share a command.

Stack memory systems, such as high bandwidth memory (HBM) systems, are used in wide variety of applications due to improved bandwidth and energy efficiency. Unlike existing memory systems using a parallel data bus, stack memory systems include a stack memory device consisting of a base die and a plurality of core dies that are mutually connected by through silicon vias (TSV) (hereinafter denoted as “through vias”). Each of the plurality of core dies includes a plurality of channels. Each of the plurality of channels may input and output data by performing a write operation and a read operation.

### SUMMARY

In accordance with an embodiment of the present disclosure, a memory device may include a first core die including first to N-th channels and a second core die including (N+1)-th to 2N-th channels. A channel among the first to N-th channels of the first core die and a channel among the (N+1)-th to 2N-th channels of the second core die may input data by receiving a write command in common and output data by receiving a read command in common.

In accordance with an embodiment of the present disclosure, a memory device may include a first core die including first to N-th channels, a second core die including (N+1)-th to 2N-th channels, a third core die including (2N+1)-th to 3N-th channels, and a fourth core die including (3N+1)-th to 4N-th channels. A channel among the first to N-th channels of the first core die and a channel among the (2N+1)-th to 3N-th channels of the third core die may input first data by receiving a write command in common and output first data by receiving a read command in common. A channel among the (N+1)-th to 2N-th channels of the second core die and a channel among the (3N+1)-th to 4N-th channels of the fourth core die may input second data by receiving the write command in common and output second data by receiving the read command in common.

In accordance with an embodiment of the present disclosure, a memory device may include a first core die including first to N-th channels, a second core die including (N+1)-th to 2N-th channels, a third core die including (2N+1)-th to 3N-th channels, and a fourth core die including (3N+1)-th to 4N-th channels. A channel among the first to N-th channels of the first core die, a channel among the (N+1)-th to 2N-th channels of the second core die, a channel among the (2N+1)-th to 3N-th channels of the third core die, and a channel among the (3N+1)-th to 4N-th channels of the fourth core die may input and output data by sharing a write command and sharing a read command.

In accordance with an embodiment of the present disclosure, a memory device may include a base die configured to output a write command and a read command and configured to input and output first and second data, a first rank including a first core die and a second core die each including a plurality of channels, and a second rank including a third core die and a fourth core die each including a plurality of channels. A channel of the plurality of channels included in the first core die and a channel of the plurality of channels included in the second core die may input and output the first data by sharing the write command and sharing the read command. A channel of the plurality of channels included in the third core die and a channel of the plurality of channels included in the fourth core die may input and output the second data by sharing the write command and sharing the read command.

### BRIEF DESCRIPTION OF THE DRAWINGS

FIG. 1 is a block diagram illustrating an embodiment of a memory device according to the present disclosure.

FIG. 2 is a block diagram illustrating an embodiment of a base die included in the memory device illustrated in FIG. 1.

FIG. 3 is a block diagram illustrating an embodiment of a memory controller included in the base die illustrated in FIG. 2.

FIG. 4 is a block diagram illustrating an embodiment of a data input and output circuit included in the base die illustrated in FIG. 2.

FIG. 5 Is a block diagram illustrating an embodiment of channels included in each of core dies illustrated in FIG. 1.

FIG. 6 is a diagram for describing an operation of the base die and the core die illustrated in FIG. 1.

FIG. 7 is a timing diagram for describing operations of the base die and the core die illustrated in FIG. 1.

FIGS. 8 to 11 are diagrams for describing an operation of the memory device according to an embodiment of the present disclosure.

FIG. 12 is a block diagram illustrating an embodiment of a memory system according to the present disclosure.

### DETAILED DESCRIPTION

In the following detailed description, the term “preset” indicates that a numerical value of a parameter is previously determined, when the parameter is used in a process or algorithm. According to different embodiments, the numerical value of a parameter may be set before or when the process or algorithm is started or while the process or algorithm is being performed.

Terms such as “first” and “second,” which are used to distinguish among various components and not to indicate a number or order of components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure is described in more detail through embodiments. The embodiments are only used to exemplify the present disclosure, and the scope of the present disclosure is not limited by the embodiments.

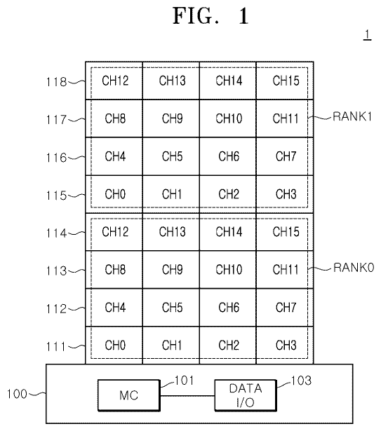

FIG. 1 illustrates an embodiment of a memory device 1 according to the present disclosure. As illustrated in FIG. 1, the memory device 1 may include a base die 100 and a plurality of core dies 111, 112, 113, 114, 115, 116, 117, and 118.

The base die 100 may include a memory controller (MC) 101 and a data input and output circuit (DATA I/O) 103.

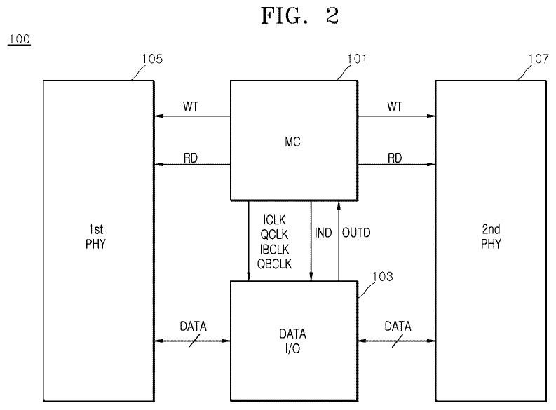

The memory controller 101 may generate commands for controlling the plurality of core dies 111, 112, 113, 114, 115, 116, 117, and 118, that is, commands WT and RD in FIG. 2. The memory controller 101 may output the command WT or RD to a plurality of channels CH0 to CH15 included in the plurality of core dies 111, 112, 113, 114, 115, 116, 117, and 118. The memory controller 101 may simultaneously output the command WT or RD to at least two of the plurality of channels CH0 to CH15 included in the plurality of core dies 111, 112, 113, 114, 115, 116, 117, and 118. The memory controller 101 may output the commands WT and RD for controlling internal operations of the plurality of core dies 111, 112, 113, 114, 115, 116, 117, and 118, for example, a write operation that stores data and a read operation that outputs data.

The data input and output circuit 103 may output data, that is, DATA in FIG. 2, to the plurality of core dies 111, 112, 113, 114, 115, 116, 117, and 118 after the start of a write operation. The data input and output circuit 103 may receive data DATA in FIG. 2 from the plurality of core dies 111, 112, 113, 114, 115, 116, 117, and 118 after the start of a read operation.

The base die 100 may simultaneously output the command WT or RD to at least two of the plurality of channels CH0 to CH15 included in the plurality of core dies 111, 112, 113, 114, 115, 116, 117, and 118. The base die 100 may input and output the data DATA through at least two of the plurality of channels CH0 to CH15 included in the plurality of core dies 111, 112, 113, 114, 115, 116, 117, and 118.

The plurality of core dies 111, 112, 113, 114, 115, 116, 117, and 118 may be vertically stacked on the base die 100. More specifically, the core die 111 may be vertically stacked on the base die 100. The core die 112 may be vertically stacked on the core die 111. The core die 113 may be vertically stacked on the core die 112. The core die 114 may be vertically stacked on the core die 113. The core die 115 may be vertically stacked on the core die 114. The core die 116 may be vertically stacked on the core die 115. The core die 117 may be vertically stacked on the core die 116. The core die 118 may be vertically stacked on the core die 117.

The plurality of core dies 111, 112, 113, 114, 115, 116, 117, and 118 may include the plurality of channels CH0 to CH15. The core die 111 may include first to fourth channels CH0 to CH3. The core die 112 may include fifth to eighth channels CH4 to CH7. The core die 113 may include ninth to twelfth channels CH8 to CH11. The core die 114 may include thirteenth to sixteenth channels CH12 to CH15. The core die 115 may include first to fourth channels CH0 to CH3. The core die 116 may include fifth to eighth channels CH4 to CH7. The core die 117 may include ninth to twelfth channels CH8 to CH11. The core die 118 may include thirteenth to sixteenth channels CH12 to CH15. For convenience of description, each of the plurality of core dies 111, 112, 113, 114, 115, 116, 117, and 118 has been illustrated as including only four channels. In other embodiments, however, each of the plurality of core dies may be implemented with various numbers of channels, like eight channels and sixteen channels, for example.

The first channel CH0 of the core die 111, the fifth channel CH4 of the core die 112, the ninth channel CH8 of the core die 113 and the thirteenth channel CH12 of the core die 114 may share a path to which the command WT or RD is input. The second channel CH1 of the core die 111, the sixth channel CH5 of the core die 112, the tenth channel CH9 of the core die 113, and the fourteenth channel CH13 of the core die 114 may share a path to which the command WT or RD is input. The third channel CH2 of the core die 111, the seventh channel CH6 of the core die 112, the eleventh channel CH10 of the core die 113, and the fifteenth channel CH14 of the core die 114 may share a path to which the command WT or RD is input. The fourth channel CH3 of the core die 111, the eighth channel CH7 of the core die 112, the twelfth channel CH11 of the core die 113, and the sixteenth channel CH15 of the core die 114 may share a path to which the command WT or RD is input.

The first channel CH0 of the core die 115, the fifth channel CH4 of the core die 116, the ninth channel CH8 of the core die 117, and the thirteenth channel CH12 of the core die 118 may share a path to which the command WT or RD is input. The second channel CH1 of the core die 115, the sixth channel CH5 of the core die 116, the tenth channel CH9 of the core die 117, and the fourteenth channel CH13 of the core die 118 may share a path to which the command WT or RD is input. The third channel CH2 of the core die 115, the seventh channel CH6 of the core die 116, the eleventh channel CH10 of the core die 117, and the fifteenth channel CH14 of the core die 118 may share at least one path to which the command WT or RD is input. The fourth channel CH3 of the core die 115, the eighth channel CH7 of the core die 116, the twelfth channel CH11 of the core die 117, and the sixteenth channel CH15 of the core die 118 may share a path to which the command WT or RD is input.

The first channel CH0 of the core die 111 and the first channel CH0 of the core die 115 may share a path to which the command WT or RD is input. The second channel CH1 of the core die 111 and the second channel CH1 of the core die 115 may share a path to which the command WT or RD is input. The third channel CH2 of the core die 111 and the third channel CH2 of the core die 115 may share a path to which the command WT or RD is input. The fourth channel CH3 of the core die 111 and the fourth channel CH3 of the core die 115 may share a path to which the command WT or RD is input.

The fifth channel CH4 of the core die 112 and the fifth channel CH4 of the core die 116 may share a path to which the command WT or RD is input. The sixth channel CH5 of the core die 112 and the sixth channel CH5 of the core die 116 may share a path to which the command WT or RD is input. The seventh channel CH6 of the core die 112 and the seventh channel CH6 of the core die 116 may share a path to which the command WT or RD is input. The eighth channel CH7 of the core die 112 and the eighth channel CH7 of the core die 116 may share a path to which the command WT or RD is input.

The ninth channel CH8 of the core die 113 and the ninth channel CH8 of the core die 117 may share a path to which the command WT or RD is input. The tenth channel CH9 of the core die 113 and the tenth channel CH9 of the core die 117 may share a path to which the command WT or RD is input. The eleventh channel CH10 of the core die 113 and the eleventh channel CH10 of the core die 117 may share a path to which the command WT or RD is input. The twelfth channel CH11 of the core die 113 and the twelfth channel CH11 of the core die 117 may share a path to which the command WT or RD is input.

The thirteenth channel CH12 of the core die 114 and the thirteenth channel CH12 of the core die 118 may share a path to which the command WT or RD is input. The fourteenth channel CH13 of the core die 114 and the fourteenth channel CH13 of the core die 118 may share a path to which the command WT or RD is input. The fifteenth channel CH14 of the core die 114 and the fifteenth channel CH14 of the core die 118 may share a path to which the command WT or RD is input. The sixteenth channel CH15 of the core die 114 and the sixteenth channel CH15 of the core die 118 may share a path to which the command WT or RD is input.

The first to fourth channels CH0 to CH3 of the core die 111, the fifth to eighth channels CH4 to CH7 of the core die 112, the ninth to twelfth channels CH8 to CH11 of the core die 113, and the thirteenth to sixteenth channels CH12 to CH15 of the core die 114 may form a first rank RANK0 for setting a bandwidth. The first to fourth channels CH0 to CH3 of the core die 115, the fifth to eighth channels CH4 to CH7 of the core die 116, the ninth to twelfth channels CH8 to CH11 of the core die 117, and the thirteenth to sixteenth channels CH12 to CH15 of the core die 118 may form a second rank RANK1 for setting a bandwidth.

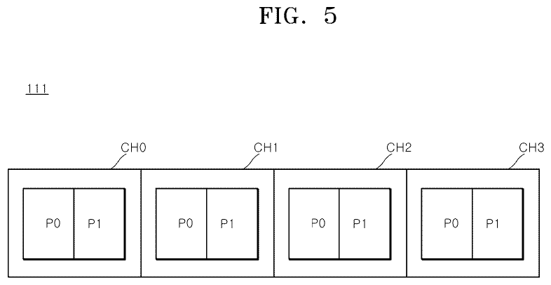

Each of the first to fourth channels CH0 to CH3 of the core die 111, each of the fifth to eighth channels CH4 to CH7 of the core die 112, each of the ninth to twelfth channels CH8 to CH11 of the core die 113, each of the thirteenth to sixteenth channels CH12 to CH15 of the core die 114, each of the first to fourth channels CH0 to CH3 of the core die 115, each of the fifth to eighth channels CH4 to CH7 of the core die 116, each of the ninth to twelfth channels CH8 to CH11 of the core die 117, and each of the thirteenth to sixteenth channels CH12 to CH15 of the core die 118 may each include a plurality of pseudo channels that independently operate to increase bandwidth. FIG. 5, for example, shows pseudo channels P0 and P1. A write operation and a read operation for each of a plurality of pseudo channels included in each of the first to sixteenth channels CH0 to CH15, for instance, P0 and P1, may be independently performed.

FIG. 2 is a block diagram illustrating an embodiment of the base die 100. As illustrated in FIG. 2, the base die 100 includes the memory controller 101, the data input and output circuit 103, a first physical layer (1^{st} PHY) 105, and a second physical layer (2^{nd} PHY) 107.

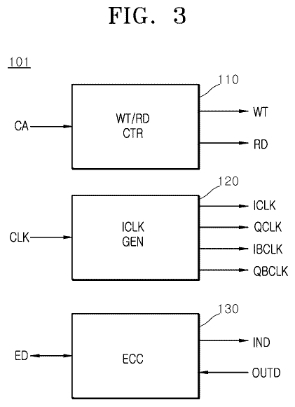

The memory controller 101 may generate a write command WT and a read command RD by decoding a command address, that is, CA in FIG. 3. The memory controller 101 may generate the write command WT, which is enabled when the command address CA having a logic level combination for performing a write operation is input. The memory controller 101 may generate the read command RD, which is enabled when the command address CA having a logic level combination for performing a read operation is input. The memory controller 101 may output the write command WT and the read command RD to the plurality of core dies 111, 112, 113, 114, 115, 116, 117, and 118 through the first physical layer 105. The memory controller 101 may output the write command WT and the read command RD to the plurality of core dies 111, 112, 113, 114, 115, 116, 117, and 118 through the second physical layer 107.

The memory controller 101 may generate a first internal clock ICLK, a second internal clock QCLK, a third internal clock IBCLK, and a fourth internal clock QBCLK by dividing the frequency of a clock CLK in FIG. 3. The memory controller 101 may sequentially generate the first internal clock ICLK, the second internal clock QCLK, the third internal clock IBCLK, and the fourth internal clock QBCLK by dividing the frequency of the clock CLK.

The memory controller 101 may generate input data IND from external data ED in FIG. 3, after the start of a write operation. The memory controller 101 may generate the input data IND by correcting any errors of the external data ED, after the start of a write operation. The memory controller 101 may generate the external data ED from output data OUTD after the start of a read operation. The memory controller 101 may generate the external data ED by correcting any errors of the output data OUTD after the start of a read operation.

The data input and output circuit 103 may generate the data DATA from the input data IND in synchronization with the first internal clock ICLK, the second internal clock QCLK, the third internal clock IBCLK, and the fourth internal clock QBCLK after the start of a write operation. The data input and output circuit 103 may generate the data DATA by serializing the input data IND in synchronization with the first internal clock ICLK, the second internal clock QCLK, the third internal clock IBCLK, and the fourth internal clock QBCLK after the start of a write operation. The data input and output circuit 103 may output the data DATA to the plurality of core dies 111, 112, 113, 114, 115, 116, 117, and 118 through the first physical layer 105 and the second physical layer 107 after the start of a write operation. The data DATA may be common data that include a plurality of bits and that are stored in a memory circuit.

The data input and output circuit 103 may generate the output data OUTD from the data DATA in synchronization with the first internal clock ICLK, the second internal clock QCLK, the third internal clock IBCLK, and the fourth internal clock QBCLK after the start of a read operation. The data input and output circuit 103 may generate the output data OUTD by deserializing the data DATA in synchronization with the first internal clock ICLK, the second internal clock QCLK, the third internal clock IBCLK, and the fourth internal clock QBCLK after the start of a read operation. The data input and output circuit 103 may receive the data DATA from the plurality of core dies 111, 112, 113, 114, 115, 116, 117, and 118 through the first physical layer 105 and the second physical layer 107 after the start of a read operation.

The first physical layer 105 may be electrically connected to the memory controller 101, the data input and output circuit 103, and the plurality of core dies 111, 112, 113, 114, 115, 116, 117, and 118. The first physical layer 105 may be electrically connected to through vias (TSVs) that penetrate the plurality of core dies 111, 112, 113, 114, 115, 116, 117, and 118. The first physical layer 105 may receive the write command WT and the read command RD from the memory controller 101. The first physical layer 105 may output the write command WT and the read command RD to the plurality of core dies 111, 112, 113, 114, 115, 116, 117, and 118. The first physical layer 105 may receive the data DATA from the data input and output circuit 103 after the start of a write operation. The first physical layer 105 may output the data DATA to the plurality of core dies 111, 112, 113, 114, 115, 116, 117, and 118 after the start of a write operation. The first physical layer 105 may receive the data DATA from the plurality of core dies 111, 112, 113, 114, 115, 116, 117, and 118 after the start of a read operation. The first physical layer 105 may output the data DATA to the data input and output circuit 103 after the start of a read operation. The first physical layer 105 may be electrically connected to the first and second channels CH0 and CH1 of the core die 111, the fifth and sixth channels CH4 and CH5 of the core die 112, the ninth and tenth channels CH8 and CH9 of the core die 113, the thirteenth and fourteenth channels CH12 and CH13 of the core die 114, the first and second channels CH0 and CH1 of the core die 115, the fifth and sixth channels CH4 and CH5 of the core die 116, the ninth and tenth channels CH8 and CH9 of the core die 117, and the thirteenth and fourteenth channels CH12 and CH13 of the core die 118.

The second physical layer 107 may be electrically connected to the memory controller 101, the data input and output circuit 103, and the plurality of core dies 111, 112, 113, 114, 115, 116, 117, and 118. The second physical layer 107 may be electrically connected to through vias (TSVs) that penetrate the plurality of core dies 111, 112, 113, 114, 115, 116, 117, and 118. The second physical layer 107 may receive the write command WT and the read command RD from the memory controller 101. The second physical layer 107 may output the write command WT and the read command RD to the plurality of core dies 111, 112, 113, 114, 115, 116, 117, and 118. The second physical layer 107 may receive the data DATA from the data input and output circuit 103 after the start of a write operation. The second physical layer 107 may output the data DATA to the plurality of core dies 111, 112, 113, 114, 115, 116, 117, and 118 after the start of a write operation. The second physical layer 107 may receive the data DATA from the plurality of core dies 111, 112, 113, 114, 115, 116, 117, and 118 after the start of a read operation. The second physical layer 107 may output the data DATA to the data input and output circuit 103 after the start of a read operation. The second physical layer 107 may be electrically connected to the third and fourth channels CH2 and CH3 of the core die 111, the seventh and eighth channels CH6 and CH7 of the core die 112, the eleventh and twelfth channels CH10 and CH11 of the core die 113, the fifteenth and sixteenth channels CH14 and CH15 of the core die 114, the third and fourth channels CH2 and CH3 of the core die 115, the seventh and eighth channels CH6 and CH7 of the core die 116, the eleventh and twelfth channels CH10 and CH11 of the core die 117, and the fifteenth and sixteenth channels CH14 and CH15 of the core die 118.

The first physical layer 105 and the second physical layer 107 may each be implemented with a physical layer (PHY) that is responsible for the generation, transmission, reception, and physical connection of a signal and data between the base die 100 and the plurality of core dies 111 to 118.

FIG. 3 is a block diagram illustrating an embodiment of the memory controller 101 included in the base die 100 illustrated in FIG. 2. The memory controller 101 may include a write read control circuit (WT/RD CTR) 110, an internal clock generation circuit (ICLK GEN) 120, and an error correction circuit (ECC) 130.

The write read control circuit 110 may generate the write command WT and the read command RD by decoding the command address CA. The write read control circuit 110 may generate the write command WT that is enabled when the command address CA having a logic level combination for performing a write operation is input. The write read control circuit 110 may generate the read command RD that is enabled when the command address CA having a logic level combination for performing a read operation is input. The command address CA may include a plurality of bits, may have a logic level combination for controlling each of a write operation and a read operation for each of the plurality of core dies 111, 112, 113, 114, 115, 116, 117, and 118, and may be input from an external device.

The internal clock generation circuit 120 may generate the first internal clock ICLK, the second internal clock QCLK, the third internal clock IBCLK, and the fourth internal clock QBCLK based on the clock CLK. The internal clock generation circuit 120 may generate the first internal clock ICLK, the second internal clock QCLK, the third internal clock IBCLK, and the fourth internal clock QBCLK by dividing the frequency of the clock CLK. For example, the internal clock generation circuit 120 may generate the first internal clock ICLK, the second internal clock QCLK, the third internal clock IBCLK, and the fourth internal clock QBCLK, each one having a frequency that is ½ of the frequency of the clock CLK, by bisecting the frequency of the clock CLK. In this case, the second internal clock QCLK may be generated later than the phase of the first internal clock ICLK by half the cycle of the clock CLK. The third internal clock IBCLK may be generated later than the phase of the second internal clock QCLK by half the cycle of the clock CLK. The fourth internal clock QBCLK may be generated later than the phase of the third internal clock IBCLK by half the cycle of the clock CLK. Accordingly, the third internal clock IBCLK and the first internal clock ICLK may be generated to have phases that are inverted with respect to each other. The fourth internal clock QBCLK and the second internal clock QCLK may be generated to have phases that are inverted relative to each other. The clock CLK may be set as a signal that periodically toggles to synchronize operations of the base die 100 and the plurality of core dies 111, 112, 113, 114, 115, 116, 117, and 118.

The error correction circuit 130 may generate the input data IND from the external data ED after the start of a write operation. The error correction circuit 130 may generate the input data IND by correcting any errors of the external data ED after the start of a write operation. The error correction circuit 130 may generate the external data ED from the output data OUTD after the start of a read operation. The error correction circuit 130 may generate the external data ED by correcting any errors of the output data OUTD after the start of a read operation. For an embodiment, the error correction circuit 130 may be implemented with a common ECC circuit that corrects any errors of data by using an error correction code (ECC). The operation of the error correction circuit 130 correcting any errors of data may be set as an operation of generating data by inverting bits of data having an error. Each of the external data ED, the input data IND, and the output data OUTD may be common data that includes a plurality of bits and that are stored in a memory circuit.

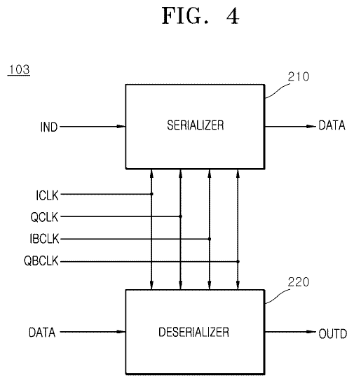

FIG. 4 is a block diagram illustrating an embodiment of the data input and output circuit 103 included in the base die 100 illustrated in FIG. 2. The data input and output circuit 103 may include a serialization circuit (SERIALIZER) 210 and a deserialization circuit (DESERIALIZER) 220.

The serialization circuit 210 may receive the input data IND in synchronization with any one of the first internal clock ICLK, the second internal clock QCLK, the third internal clock IBCLK, and the fourth internal clock QBCLK after the start of a write operation. The serialization circuit 210 may generate the data DATA by serializing the input data IND after the start of a write operation.

The deserialization circuit 220 may receive the data DATA in synchronization with any one of the first internal clock ICLK, the second internal clock QCLK, the third internal clock IBCLK, and the fourth internal clock QBCLK after the start of a read operation. The deserialization circuit 220 may generate the output data OUTD by deserializing the data DATA that are received after the start of a read operation.

FIG. 5 is a block diagram illustrating an embodiment of channels included in each of the core dies 111 to 118.

As illustrated in FIG. 5, the core die 111 may include the first to fourth channels CH0 to CH3. Each of the first to fourth channels CH0 to CH3 may include a first pseudo channel P0 and a second pseudo channel P1 that independently operate to increase bandwidth. A write operation and a read operation for each of the first pseudo channel P0 and the second pseudo channel P1 may be independently performed.

The core dies 112, 113, 114, 115, 116, 117, and 118 may each implemented with the same construction as the core die 111.

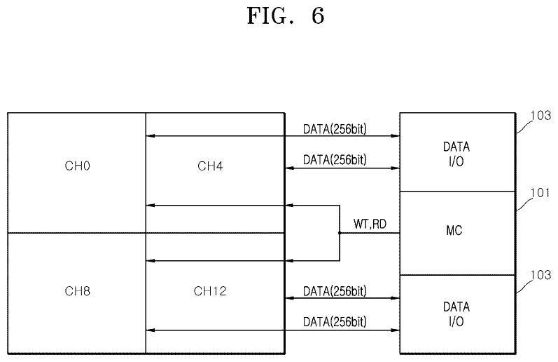

FIG. 6 is a diagram for describing operations of the base die 100 and the core dies 111 to 114.

The memory controller 101 may simultaneously output the write command WT to the first channel CH0 of the core die 111 and the fifth channel CH4 of the core die 112 through the first physical layer 105. The data input and output circuit 103 may output the data DATA of 256 bits to the first channel CH0 of the core die 111 through the first physical layer 105 after the start of a write operation. The first channel CH0 of the core die 111 may store the data DATA of 256 bits. The data input and output circuit 103 may output the data DATA of 256 bits to the fifth channel CH4 of the core die 112 through the first physical layer 105 after the start of a write operation. The fifth channel CH4 of the core die 112 may store the data DATA of 256 bits.

The memory controller 101 may simultaneously output the write command WT to the ninth channel CH8 of the core die 113 and the thirteenth channel CH12 of the core die 114 through the first physical layer 105. The data input and output circuit 103 may output the data DATA of 256 bits to the ninth channel CH8 of the core die 113 through the first physical layer 105 after the start of a write operation. The ninth channel CH8 of the core die 113 may store the data DATA of 256 bits. The data input and output circuit 103 may output the data DATA of 256 bits to the thirteenth channel CH12 of the core die 114 through the first physical layer 105 after the start of a write operation. The thirteenth channel CH12 of the core die 114 may store the data DATA of 256 bits.

The memory controller 101 may simultaneously output the read command RD to the first channel CH0 of the core die 111 and the fifth channel CH4 of the core die 112 through the first physical layer 105. The first channel CH0 of the core die 111 may output the data DATA of 256 bits through the first physical layer 105. The data input and output circuit 103 may receive the data DATA of 256 bits that are output from the first channel CH0 of the core die 111 through the first physical layer 105 after the start of a read operation, and may generate the output data OUTD by deserializing the data DATA. The memory controller 101 may generate the external data ED by correcting any errors of the output data OUTD after the start of a read operation, and may output the external data ED to an external device. The fifth channel CH4 of the core die 112 may output the data DATA of 256 bits through the first physical layer 105. The data input and output circuit 103 may receive the data DATA of 256 bits that are output from the fifth channel CH4 of the core die 112 through the first physical layer 105 after the start of a read operation, and may generate the output data OUTD by deserializing the data DATA. The memory controller 101 may generate the external data ED by correcting any errors of the output data OUTD after the start of a read operation, and may output the external data ED to an external device.

The memory controller 101 may simultaneously output the read command RD to the ninth channel CH8 of the core die 113 and the thirteenth channel CH12 of the core die 114 through the first physical layer 105. The ninth channel CH8 of the core die 113 may output the data DATA of 256 bits through the first physical layer 105. The data input and output circuit 103 may receive the data DATA of 256 bits that are output from the ninth channel CH8 of the core die 113 through the first physical layer 105 after the start of a read operation, and may generate the output data OUTD by deserializing the data DATA. The memory controller 101 may generate the external data ED by correcting any errors of the output data OUTD after the start of a read operation, and may output the external data ED to an external device. The thirteenth channel CH12 of the core die 114 may output the data DATA of 256 bits through the first physical layer 105. The data input and output circuit 103 may receive the data DATA of 256 bits that are output from the thirteenth channel CH12 of the core die 114 through the first physical layer 105 after the start of a read operation, and may generate the output data OUTD by deserializing the data DATA. The memory controller 101 may generate the external data ED by correcting any errors of the output data OUTD after the start of a read operation, and may output the external data ED to an external device.

In an embodiment of the present disclosure, the data DATA have been implemented so that the data DATA are input and output as 256 bits, but the data DATA may be implemented with various numbers of bits, such as 128 bits, 512 bits, or 1024 bits, for example.

As described above, the memory device 1 can input and output the data DATA through a bandwidth (512 bits) wider than a bandwidth (256 bits) through which the data DATA are input and output through a single channel because at least two of the plurality of channels included in the plurality of core dies 111 to 118 input and output data, respectively, by sharing the command WT or RD.

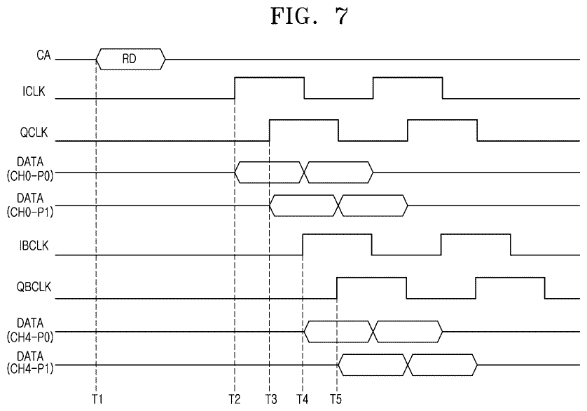

FIG. 7 is a timing diagram for describing operations of the base die 100 and the core dies 111 and 112. Operations of the base die 100 and the core die 111 are described with reference to FIG. 7. In this case, read operations for the first channel CH0 of the core die 111 and the fifth channel CH4 of the core die 112 are described as follows.

At timing T1, the memory controller 101 generates the read command RD that is enabled when the command address CA having a logic level combination for performing a read operation is input.

The memory controller 101 simultaneously outputs the read command RD to the first channel CH0 of the core die 111 and the fifth channel CH4 of the core die 112 through the first physical layer 105.

At timing T2, the memory controller 101 generates the first internal clock ICLK by dividing the frequency of the clock CLK.

The data input and output circuit 103 receives the data DATA of 256 bits that are generated by the first pseudo channel P0 included in the first channel CH0 of the core die 111, in synchronization with the first internal clock ICLK, and generates the output data OUTD by deserializing the data DATA. The memory controller 101 generates the external data ED by correcting any errors of the output data OUTD after the start of a read operation, and outputs the external data ED to an external device.

At timing T3, the memory controller 101 generates the second internal clock QCLK by dividing the frequency of the clock CLK.

The data input and output circuit 103 receives the data DATA of 256 bits that are generated by the second pseudo channel P1 included in the first channel CH0 of the core die 111, in synchronization with the second internal clock QCLK, and generates the output data OUTD by deserializing the data DATA. The memory controller 101 generates the external data ED by correcting any errors of the output data OUTD after the start of a read operation, and outputs the external data ED to the external device.

At timing T4, the memory controller 101 generates the third internal clock IBCLK by dividing the frequency of the clock CLK.

The data input and output circuit 103 receives the data DATA of 256 bits that are generated by the first pseudo channel P0 included in the fifth channel CH4 of the core die 112, in synchronization with the third internal clock IBCLK, and generates the output data OUTD by deserializing the data DATA. The memory controller 101 generates the external data ED by correcting any errors of the output data OUTD after the start of a read operation, and outputs the external data ED to the external device.

At timing T5, the memory controller 101 generates the fourth internal clock QBCLK by dividing the frequency of the clock CLK.

The data input and output circuit 103 receives the data DATA of 256 that are generated by the second pseudo channel P1 included in the fifth channel CH4 of the core die 112 in synchronization with the fourth internal clock QBCLK, and generates the output data OUTD by deserializing the data DATA. The memory controller 101 generates the external data ED by correcting any errors of the output data OUTD after the start of a read operation, and outputs the external data ED to the external device.

As described above, the memory device 1 can input and output the data DATA through a bandwidth (512 bits) wider than a bandwidth (256 bits) through which the data DATA are input and output through one channel because at least two of the plurality of channels included in the plurality of core dies 111 to 118 input and output data, respectively, by sharing the command WT or RD.

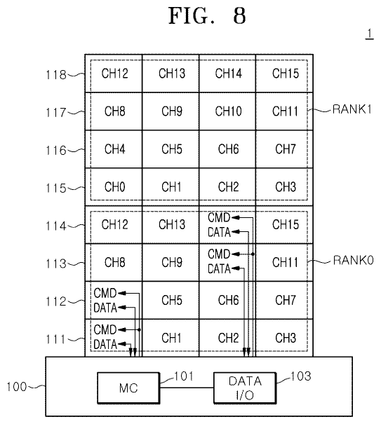

FIG. 8 is a diagram for describing an operation of the memory device 1 according to an embodiment of the present disclosure. An operation of the memory device 1 is described with reference to FIG. 8. In this case, write operations and read operations for the first channel CH0 of the core die 111 and the fifth channel CH4 of the core die 112 that neighbor each other and the eleventh channel CH10 of the core die 113 and the fifteenth channel CH14 of the core die 114 that neighbor each other are described as follows.

The memory controller 101 of the base die 100 may simultaneously output the command CMD for a write operation to the first channel CH0 of the core die 111 and the fifth channel CH4 of the core die 112 through the first physical layer 105. The memory controller 101 of the base die 100 may simultaneously output the command CMD for a write operation to the eleventh channel CH10 of the core die 113 and the fifteenth channel CH14 of the core die 114 through the second physical layer 107. The command CMD illustrated in FIG. 8 may include a write command, WT in FIG. 2, that performs a write operation.

The first channel CH0 of the core die 111 and the fifth channel CH4 of the core die 112 are channels that neighbor each other. The eleventh channel CH10 of the core die 113 and the fifteenth channel CH14 of the core die 114 are channels that neighbor each other.

The data input and output circuit 103 of the base die 100 may output the data DATA of 256 bits to the first channel CH0 of the core die 111 and output the data DATA of 256 bits to the fifth channel CH4 of the core die 112 through the first physical layer 105 after the start of a write operation. The data input and output circuit 103 of the base die 100 may output the data DATA of 256 bits to the eleventh channel CH10 of the core die 113 and output the data DATA of 256 bits to the fifteenth channel CH14 of the core die 114 through the second physical layer 107 after the start of a write operation.

The first channel CH0 of the core die 111 may store the data DATA of 256 bits that are received through the first physical layer 105 after the start of a write operation. The fifth channel CH4 of the core die 112 may store the data DATA of 256 bits that are received through the first physical layer 105 after the start of a write operation. The first channel CH0 of the core die 111 and the fifth channel CH4 of the core die 112 may store the combined data DATA of 512 bits after the start of a single write operation.

The eleventh channel CH10 of the core die 113 may store the data DATA of 256 bits that are received through the second physical layer 107 after the start of a write operation. The fifteenth channel CH14 of the core die 114 may store the data DATA of 256 bits that are received through the second physical layer 107 after the start of a write operation. The eleventh channel CH10 of the core die 113 and the fifteenth channel CH14 of the core die 114 may store the combined data DATA of 512 bits after the start of a single write operation.

The memory controller 101 of the base die 100 may simultaneously output the command CMD for a read operation to the first channel CH0 of the core die 111 and the fifth channel CH4 of the core die 112 through the first physical layer 105. The memory controller 101 of the base die 100 may simultaneously output the command CMD for a read operation to the eleventh channel CH10 of the core die 113 and the fifteenth channel CH14 of the core die 114 through the second physical layer 107. The command CMD illustrated in FIG. 8 may include a read command, RD in FIG. 2, that performs a read operation.

The first channel CH0 of the core die 111 may output the data DATA of 256 bits through the first physical layer 105 after the start of a read operation. The fifth channel CH4 of the core die 112 may output the data DATA of 256 bits through the first physical layer 105 after the start of a read operation. The first channel CH0 of the core die 111 and the fifth channel CH4 of the core die 112 may output the combined data DATA of 512 bits after the start of one read operation.

The eleventh channel CH10 of the core die 113 may output the data DATA of 256 bits through the second physical layer 107 after the start of a read operation. The fifteenth channel CH14 of the core die 114 may output the data DATA of 256 bits through the second physical layer 107 after the start of a read operation. The eleventh channel CH10 of the core die 113 and the fifteenth channel CH14 of the core die 114 may output the combined data DATA of 512 bits after the start of one read operation.

The data input and output circuit 103 of the base die 100 may receive the data DATA of 256 bits from the first channel CH0 of the core die 111 through the first physical layer 105 after the start of a read operation. The data input and output circuit 103 of the base die 100 may receive the data DATA of 256 bits from the fifth channel CH4 of the core die 112 through the first physical layer 105 after the start of a read operation.

The data input and output circuit 103 of the base die 100 may receive the data DATA of 256 bits from the eleventh channel CH10 of the core die 113 through the second physical layer 107 after the start of a read operation. The data input and output circuit 103 of the base die 100 may receive the data DATA of 256 bits from the fifteenth channel CH14 of the core die 114 through the second physical layer 107 after the start of a read operation.

The memory device 1 can input and output the data DATA through a bandwidth (512 bits) wider than a bandwidth (256 bits) through which the data DATA are input and output through one channel because two channels that neighbor each other, among the plurality of channels included in the plurality of core dies 111 to 118, input and output data, respectively, by sharing the command CMD.

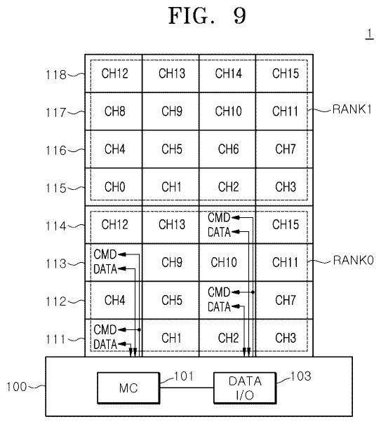

FIG. 9 is a diagram for describing an operation of the memory device 1 according to an embodiment of the present disclosure. An operation of the memory device 1 is described with reference to FIG. 9. In this case, write operations and read operations for the first channel CH0 of the core die 111 and the ninth channel CH8 of the core die 113 that are spaced apart from each other and the seventh channel CH6 of the core die 112 and the fifteenth channel CH14 of the core die 114 that are spaced apart from each other are described as follows.

The memory controller 101 of the base die 100 may output the command CMD for a write operation to the first channel CH0 of the core die 111 and the ninth channel CH8 of the core die 113 through the first physical layer 105. The memory controller 101 of the base die 100 may output the command CMD for a write operation to the seventh channel CH6 of the core die 112 and the fifteenth channel CH14 of the core die 114 through the second physical layer 107. The command CMD illustrated in FIG. 9 may include a write command, WT in FIG. 2, that performs a write operation.

The first channel CH0 of the core die 111 and the ninth channel CH8 of the core die 113 are spaced apart from each other by the core die 112. The seventh channel CH6 of the core die 112 and the fifteenth channel CH14 of the core die 114 are spaced apart from each other by the core die 113.

The data input and output circuit 103 of the base die 100 may output the data DATA of 256 bits to the first channel CH0 of the core die 111 and the data DATA of 256 bits to the ninth channel CH8 of the core die 113 through the first physical layer 105 after the start of a write operation. The data input and output circuit 103 of the base die 100 may output the data DATA of 256 bits to the seventh channel CH6 of the core die 112 and the data DATA of 256 bits to the fifteenth channel CH14 of the core die 114 through the second physical layer 107 after the start of a write operation.

The first channel CH0 of the core die 111 may store the data DATA of 256 bits that are received through the first physical layer 105 after the start of a write operation. The ninth channel CH8 of the core die 113 may store the data DATA of 256 bits that are received through the first physical layer 105 after the start of a write operation. The first channel CH0 of the core die 111 and the ninth channel CH8 of the core die 113 may store the combined data DATA of 512 bits after the start of a single write operation.

The seventh channel CH6 of the core die 112 may store the data DATA of 256 bits that are received through the second physical layer 107 after the start of a write operation. The fifteenth channel CH14 of the core die 114 may store the data DATA of 256 bits that are received through the second physical layer 107 after the start of a write operation. The seventh channel CH6 of the core die 112 and the fifteenth channel CH14 of the core die 114 may store the combined data DATA of 512 bits after the start of a single write operation.

The memory controller 101 of the base die 100 may output the command CMD for a read operation to the first channel CH0 of the core die 111 and the ninth channel CH8 of the core die 113 through the first physical layer 105. The memory controller 101 of the base die 100 may output the command CMD for a read operation to the seventh channel CH6 of the core die 112 and the fifteenth channel CH14 of the core die 114 through the second physical layer 107. The command CMD illustrated in FIG. 9 may include a read command, RD in FIG. 2, that performs a read operation.

The first channel CH0 of the core die 111 may output the data DATA of 256 bits through the first physical layer 105 after the start of a read operation. The ninth channel CH8 of the core die 113 may output the data DATA of 256 bits through the first physical layer 105 after the start of a read operation. The first channel CH0 of the core die 111 and the ninth channel CH8 of the core die 113 may output the combined data DATA of 512 bits after the start of one read operation.

The seventh channel CH6 of the core die 112 may output the data DATA of 256 bits through the second physical layer 107 after the start of a read operation. The fifteenth channel CH14 of the core die 114 may output the data DATA of 256 bits through the second physical layer 107 after the start of a read operation. The seventh channel CH6 of the core die 112 and the fifteenth channel CH14 of the core die 114 may output the combined data DATA of 512 bits after the start of one read operation.

The data input and output circuit 103 of the base die 100 may receive the data DATA of 256 bits from the first channel CH0 of the core die 111 through the first physical layer 105 after the start of a read operation. The data input and output circuit 103 of the base die 100 may receive the data DATA of 256 bits from the ninth channel CH8 of the core die 113 through the first physical layer 105 after the start of a read operation.

The data input and output circuit 103 of the base die 100 may receive the data DATA of 256 bits from the seventh channel CH6 of the core die 112 through the second physical layer 107 after the start of a read operation. The data input and output circuit 103 of the base die 100 may receive the data DATA of 256 bits from the fifteenth channel CH14 of the core die 114 through the second physical layer 107 after the start of a read operation.

As described above, the memory device 1 can input and output the data DATA through a bandwidth (512 bits) wider than a bandwidth (256 bits) through which the data DATA are input and output through one channel because two channels that are spaced apart from each other, among the plurality of channels included in the plurality of core dies 111 to 118, input and output data, respectively, by sharing the command CMD.

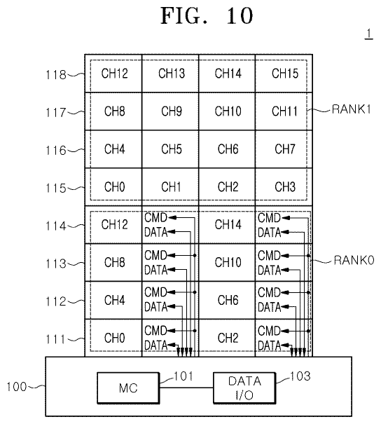

FIG. 10 is a diagram for describing an operation of the memory device 1 according to an embodiment of the present disclosure. An operation of the memory device 1 is described with reference to FIG. 10. Write operations and read operations for the second channel CH1 of the core die 111, the sixth channel CH5 of the core die 112, the tenth channel CH9 of the core die 113, and the fourteenth channel CH13 of the core die 114 that neighbor each other and write operations and read operations for the fourth channel CH3 of the core die 111, the eighth channel CH7 of the core die 112, the twelfth channel CH11 of the core die 113, and the sixteenth channel CH15 of the core die 114 that neighbor each other are described as follows.

The memory controller 101 of the base die 100 may output the command CMD for a write operation to the second channel CH1 of the core die 111, the sixth channel CH5 of the core die 112, the tenth channel CH9 of the core die 113, and the fourteenth channel CH13 of the core die 114 through the first physical layer 105. The memory controller 101 of the base die 100 may output the command CMD for a write operation to the fourth channel CH3 of the core die 111, the eighth channel CH7 of the core die 112, the twelfth channel CH11 of the core die 113, and the sixteenth channel CH15 of the core die 114 through the second physical layer 107. The command CMD illustrated in FIG. 10 may include a write command, WT in FIG. 2, that performs a write operation.

The second channel CH1 of the core die 111, the sixth channel CH5 of the core die 112, the tenth channel CH9 of the core die 113, and the fourteenth channel CH13 of the core die 114 are channels that neighbor each other. The fourth channel CH3 of the core die 111, the eighth channel CH7 of the core die 112, the twelfth channel CH11 of the core die 113, and the sixteenth channel CH15 of the core die 114 are channels that neighbor each other.

The data input and output circuit 103 of the base die 100 may output the data DATA of 256 bits to the second channel CH1 of the core die 111, the data DATA of 256 bits to the sixth channel CH5 of the core die 112, the data DATA of 256 bits to the tenth channel CH9 of the core die 113, and the data DATA of 256 bits to the fourteenth channel CH13 of the core die 114 through the first physical layer 105 after the start of a write operation. The data input and output circuit 103 of the base die 100 may output the data DATA of 256 bits to the fourth channel CH3 of the core die 111, the data DATA of 256 bits to the eighth channel CH7 of the core die 112, the data DATA of 256 bits to the twelfth channel CH11 of the core die 113, and the data DATA of 256 bits to the sixteenth channel CH15 of the core die 114 through the second physical layer 107 after the start of a write operation.

The second channel CH1 of the core die 111 may store the data DATA of 256 bits that are received through the first physical layer 105 after the start of a write operation. The sixth channel CH5 of the core die 112 may store the data DATA of 256 bits that are received through the first physical layer 105 after the start of a write operation. The tenth channel CH9 of the core die 113 may store the data DATA of 256 bits that are received through the first physical layer 105 after the start of a write operation. The fourteenth channel CH13 of the core die 114 may store the data DATA of 256 bits that are received through the first physical layer 105 after the start of a write operation. The second channel CH1 of the core die 111, the sixth channel CH5 of the core die 112, the tenth channel CH9 of the core die 113, and the fourteenth channel CH13 of the core die 114 may store the combined data DATA of 1024 bits after the start of a single write operation.

The fourth channel CH3 of the core die 111 may store the data DATA of 256 bits that are received through the second physical layer 107 after the start of a write operation. The eighth channel CH7 of the core die 112 may store the data DATA of 256 bits that are received through the second physical layer 107 after the start of a write operation. The twelfth channel CH11 of the core die 113 may store the data DATA of 256 bits that are received through the second physical layer 107 after the start of a write operation. The sixteenth channel CH15 of the core die 114 may store the data DATA of 256 bits that are received through the second physical layer 107 after the start of a write operation. The fourth channel CH3 of the core die 111, the eighth channel CH7 of the core die 112, the twelfth channel CH11 of the core die 113, and the sixteenth channel CH15 of the core die 114 may store the combined data DATA of 1024 bits after the start of a single write operation.

The memory controller 101 of the base die 100 may output the command CMD for a read operation to the second channel CH1 of the core die 111, the sixth channel CH5 of the core die 112, the tenth channel CH9 of the core die 113, and the fourteenth channel CH13 of the core die 114 through the first physical layer 105. The memory controller 101 of the base die 100 may output the command CMD for a read operation to the fourth channel CH3 of the core die 111, the eighth channel CH7 of the core die 112, the twelfth channel CH11 of the core die 113, and the sixteenth channel CH15 of the core die 114 through the second physical layer 107. The command CMD illustrated in FIG. 10 may include a read command, RD in FIG. 2, that performs a read operation.

The second channel CH1 of the core die 111 may output the data DATA of 256 bits through the first physical layer 105 after the start of a read operation. The sixth channel CH5 of the core die 112 may output the data DATA of 256 bits through the first physical layer 105 after the start of a read operation. The tenth channel CH9 of the core die 113 may output the data DATA of 256 bits through the first physical layer 105 after the start of a read operation. The fourteenth channel CH13 of the core die 114 may output the data DATA of 256 bits through the first physical layer 105 after the start of a read operation. The second channel CH1 of the core die 111, the sixth channel CH5 of the core die 112, the tenth channel CH9 of the core die 113, and the fourteenth channel CH13 of the core die 114 may output the combined data DATA of 1024 bits after the start of one read operation.

The fourth channel CH3 of the core die 111 may output the data DATA of 256 bits through the second physical layer 107 after the start of a read operation. The eighth channel CH7 of the core die 112 may output the data DATA of 256 bits through the second physical layer 107 after the start of a read operation. The twelfth channel CH11 of the core die 113 may output the data DATA of 256 bits through the second physical layer 107 after the start of a read operation. The sixteenth channel CH15 of the core die 114 may output the data DATA of 256 bits through the second physical layer 107 after the start of a read operation. The fourth channel CH3 of the core die 111, the eighth channel CH7 of the core die 112, the twelfth channel CH11 of the core die 113, and the sixteenth channel CH15 of the core die 114 may output the combined data DATA of 1024 bits after the start of one read operation.

The data input and output circuit 103 of the base die 100 may receive the data DATA of 256 bits from the second channel CH1 of the core die 111, the data DATA of 256 bits from the sixth channel CH5 of the core die 112, the data DATA of 256 bits from the tenth channel CH9 of the core die 113, and the data DATA of 256 bits from the fourteenth channel CH13 of the core die 114 through the first physical layer 105 after the start of a read operation.

The data input and output circuit 103 of the base die 100 may receive the data DATA of 256 bits from the fourth channel CH3 of the core die 111, the data DATA of 256 bits from the eighth channel CH7 of the core die 112, the data DATA of 256 bits from the twelfth channel CH11 of the core die 113, and the data DATA of 256 bits from the sixteenth channel CH15 of the core die 114 through the second physical layer 107 after the start of a read operation. The data input and output circuit 103 of the base die 100 may receive the data DATA of 256 bits from the fifteenth channel CH14 of the core die 114 through the second physical layer 107 after the start of a read operation.

As described above, the memory device 1 can input and output the data DATA through a bandwidth (1024 bits) wider than a bandwidth (256 bits) through which the data DATA are input and output through a single channel because four channels that neighbor each other, among the plurality of channels included in the plurality of core dies 111 to 118, input and output data, respectively, by sharing the command CMD.

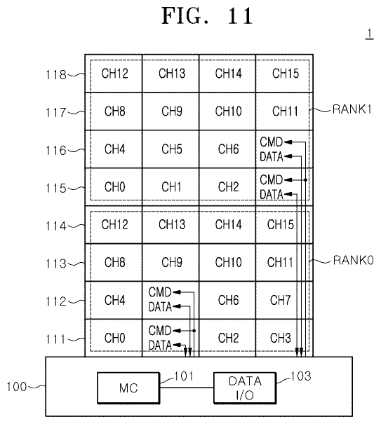

FIG. 11 is a diagram for describing an operation of the memory device 1 according to an embodiment of the present disclosure. An operation of the memory device 1 is described with reference to FIG. 11. In this case, write operations and read operations for the second channel CH1 of the core die 111 and the sixth channel CH5 of the core die 112 that are included in the first rank RANK0 and write operations and read operations for the fourth channel CH3 of the core die 115 and the eighth channel CH7 of the core die 116 that are included in the second rank RANK1 are described as follows.

The memory controller 101 of the base die 100 may output the command CMD for a write operation to the second channel CH1 of the core die 111 and the sixth channel CH5 of the core die 112 through the first physical layer 105. The memory controller 101 of the base die 100 may output the command CMD for a write operation to the fourth channel CH3 of the core die 115 and the eighth channel CH7 of the core die 116 through the second physical layer 107. The command CMD illustrated in FIG. 11 may include a write command, WT in FIG. 2, that performs a write operation.

The data input and output circuit 103 of the base die 100 may output the data DATA of 256 bits to the second channel CH1 of the core die 111 and the data DATA of 256 bits to the sixth channel CH5 of the core die 112 through the first physical layer 105 after the start of a write operation. The data input and output circuit 103 of the base die 100 may output the data DATA of 256 bits to the fourth channel CH3 of the core die 115 and the data DATA of 256 bits to the eighth channel CH7 of the core die 116 through the second physical layer 107 after the start of a write operation.

The second channel CH1 of the core die 111 may store the data DATA of 256 bits that are received through the first physical layer 105 after the start of a write operation. The sixth channel CH5 of the core die 112 may store the data DATA of 256 bits that are received through the first physical layer 105 after the start of a write operation. The second channel CH1 of the core die 111 and the sixth channel CH5 of the core die 112 may store the combined data DATA of 512 bits after the start of a single write operation.

The fourth channel CH3 of the core die 115 may store the data DATA of 256 bits that are received through the second physical layer 107 after the start of a write operation. The eighth channel CH7 of the core die 116 may store the data DATA of 256 bits that are received through the second physical layer 107 after the start of a write operation. The fourth channel CH3 of the core die 115 and the eighth channel CH7 of the core die 116 may store the combined data DATA of 512 bits after the start of a single write operation.

The memory controller 101 of the base die 100 may output the command CMD for a read operation to the second channel CH1 of the core die 111, the sixth channel CH5 of the core die 112 through the first physical layer 105. The memory controller 101 of the base die 100 may output the command CMD for a read operation to the fourth channel CH3 of the core die 115 and the eighth channel CH7 of the core die 116 through the second physical layer 107. The command CMD illustrated in FIG. 11 may include a read command, RD in FIG. 2, that performs a read operation.

The second channel CH1 of the core die 111 may output the data DATA of 256 bits through the first physical layer 105 after the start of a read operation. The sixth channel CH5 of the core die 112 may output the data DATA of 256 bits through the first physical layer 105 after the start of a read operation. The second channel CH1 of the core die 111 and the sixth channel CH5 of the core die 112 may output the combined data DATA of 512 bits after the start of one read operation.

The fourth channel CH3 of the core die 115 may output the data DATA of 256 bits through the second physical layer 107 after the start of a read operation. The eighth channel CH7 of the core die 116 may output the data DATA of 256 bits through the second physical layer 107 after the start of a read operation. The fourth channel CH3 of the core die 115 and the eighth channel CH7 of the core die 116 may output the combined data DATA of 512 bits after the start of one read operation.

The data input and output circuit 103 of the base die 100 may receive the data DATA of 256 bits from the second channel CH1 of the core die 111 through the first physical layer 105 after the start of a read operation. The data input and output circuit 103 of the base die 100 may receive the data DATA of 256 bits from the sixth channel CH5 of the core die 112 through the first physical layer 105 after the start of a read operation.

The data input and output circuit 103 of the base die 100 may receive the data DATA of 256 bits from the fourth channel CH3 of the core die 115 through the second physical layer 107 after the start of a read operation. The data input and output circuit 103 of the base die 100 may receive the data DATA of 256 bits from the eighth channel CH7 of the core die 116 through the second physical layer 107 after the start of a read operation.

The memory device 1 can input and output the data DATA through a bandwidth (512 bits) wider than a bandwidth (256 bits) through which the data DATA are input and output through a single channel because two channels, among the plurality of channels included in the plurality of core dies 111 to 118, input and output data, respectively, by sharing the command CMD.

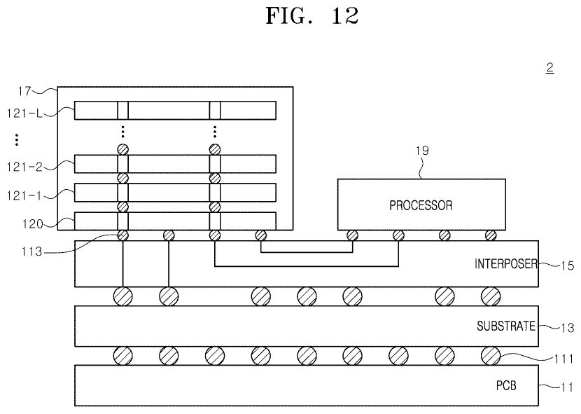

FIG. 12 is a block diagram illustrating an embodiment of a memory system 2 according to the present disclosure.

As illustrated in FIG. 12, the memory system 2 includes a printed circuit board (PCB) 11, a substrate 13, an interposer 15, a memory device 17, and a processor 19.

The PCB 11 interconnects several electronic parts to form an electronic circuit (not illustrated). The electronic circuit may include the memory system 2. A copper layer, a solder mask, a silk screen, etc. may be formed on the PCB 11. A circuit path that transmits a signal or power is formed in the copper layer. The solder mask prevents damage to a circuit and protects a specific region in which a part may be soldered. Furthermore, the silk screen indicates the location or information of an electronic part in the form of characters or symbols printed on a surface of the PCB 11.

The substrate 13 is formed over the PCB 11 through bump pads 111, for example, and mechanically supports the interposer 15, the memory device 17, and the processor 19. The substrate 13 is used as an insulator in common, that is, a material that is a physical base of the PCB 11. The material of the substrate 13 includes FR4 that is an insulator made of glass fiber and epoxy resin, ceramic which is basically used in a high frequency circuit or a high temperature environment because the ceramic can withstand a high temperature and has excellent thermal conductivity, and polyimide that is used as a basic material of a flexible PCB due to a flexible characteristic.

The interposer 15 is formed over the substrate 13 through the bump pads 111, and includes wires that connect electronic parts (e.g., the memory device 17 and the processor 19) which do not have the same form factor or pin arrangement. The interposer 15 may convert signals at different interfaces.

The memory device 17 is formed over the interposer 15 through micro bump pads 113. The memory device 17 may store data that are applied by the processor 19 or output data stored in the memory device 17 to the processor 19, under the control of the processor 19. The memory device 17 includes a base die 120 and a plurality of core dies 121-1 to 121-L. The core dies 121-1 to 121-L may be stacked over the base die 120 through the micro bump pads 113. The base die 120 and the core dies 121-1 to 121-L are vertically connected through vias TSVs. The number L of core dies 121-1 to 121-L, for example, may be 4, 8, 12, or 16. For instance, when each of the core dies 121-1 to 121-12 has eight channels, each of the core dies 121-1 to 121-4, each of the core dies 121-5 to 121-8, and each of the core dies 121-9 to 121-12 may each include 32 channel regions, and may transmit and receive data to and from the processor 19 in a rank unit consisting of 32 channels.

The base die 120 controls data transmitted between the processor 19 and the core dies 121-1 to 121-L. The base die 120 may output the command WT or RD in FIG. 2 to at least two of the plurality of channels included in the plurality of core dies 121-1 to 121-L, that is, CH0 to CH15 in FIG. 1. The base die 120 may input and output the data DATA through at least two of the plurality of channels CH0 to CH15 included in the plurality of core dies 121-1 to 121-L. Each of the plurality of core dies 121-1 to 121-L may perform a write operation that stores the data DATA in at least two of the plurality of channels, that is, CH0 to CH15 in FIG. 1, and a read operation that outputs the data DATA that are stored in at least two of the plurality of channels, that is, CH0 to CH15 in FIG. 1. The memory device 17 can input and output the data DATA through a bandwidth (512 bits or 1024 bits) wider than a bandwidth (256 bits) through which the data DATA are input and output through a single channel because at least two of the plurality of channels included in the plurality of core dies 121-1 to 121-L input and output the data DATA, respectively, by sharing the command WT or RD in FIG. 2.

What is claimed is:

1. A memory device comprising:
a first core die comprising first to N-th channels; and
a second core die comprising (N+1)-th to 2N-th channels,
wherein a first channel among the first to N-th channels of the first core die and a second channel among the (N+1)-th to 2N-th channels of the second core die input data by receiving a write command in common and output data by receiving a read command in common.

2. The memory device of claim 1, wherein:
the second core die is stacked over the first core die in a stacking direction; and
the first channel of the first core die and the second channel of the second core die that receive the write command in common and the read command in common are aligned in the stacking direction.

3. The memory device of claim 2, wherein the first channel of the first core die and the second channel of the second core die that receive the write command in common and the read command in common are adjacent to each other in the stacking direction.

4. The memory device of claim 1, further comprising a base die configured to:
output the write command in common and the read command in common to the first channel among the first to N-th channels and the second channel among the (N+1)-th to 2N-th channels; and
input and output the data through the first channel among the first to N-th channels and of the second channel among the (N+1)-th to 2N-th channels.

5. The memory device of claim 4, wherein the base die comprises:
a memory controller configured to generate the write command and the read command based on a command address, configured to generate first to fourth internal clocks by dividing a frequency of a clock, configured to generate input data from external data after the start of a write operation, and configured to generate the external data from output data after the start of a read operation;
a first physical layer electrically connected to the first to N-th channels and the (N+1)-th to 2N-th channels, the first physical layer configured to output the write command, the read command, and the data to the first to N-th channels and the (N+1)-th to 2N-th channels and configured to receive the data from the first to N-th channels and the (N+1)-th to 2N-th channels;
a second physical layer electrically connected to the first to N-th channels and the (N+1)-th to 2N-th channels, the second physical layer configured to output the write command, the read command, and the data to the first to N-th channels and the (N+1)-th to 2N-th channels and configured to receive the data from the first to N-th channels and the (N+1)-th to 2N-th channels; and
a data input and output circuit configured to, in synchronization with the first to fourth internal clocks:
generate, after the start of the write operation, the data from the input data, and
generate, after the start of the read operation, the output data from the data.

6. The memory device of claim 5, wherein the memory controller comprises:
a write read control circuit configured to generate the write command and the read command by decoding the command address;
an internal clock generation circuit configured to generate the first to fourth internal clocks by dividing the frequency of the clock; and
an error correction circuit configured to:
generate the input data by correcting an error of the external data after the start of the write operation; and
output the output data as the external data by correcting an error of the output data after the start of the read operation.

7. The memory device of claim 5, wherein the data input and output circuit comprises:
a serialization circuit configured to receive and serialize the input data in synchronization with the first to fourth internal clocks after the start of the write operation; and
a deserialization circuit configured to receive the data in synchronization with the first to fourth internal clocks after the start of the read operation and configured to generate the output data by deserializing the data.

8. A memory device comprising:
a first core die comprising first to N-th channels;
a second core die comprising (N+1)-th to 2N-th channels;
a third core die comprising (2N+1)-th to 3N-th channels; and
a fourth core die comprising (3N+1)-th to 4N-th channels,
wherein a first channel among the first to N-th channels of the first core die and a third channel among the (2N+1)-th to 3N-th channels of the third core die input first data by receiving a write command in common and output the first data by receiving a read command in common, and
wherein a second channel, among the (N+1)-th to 2N-th channels of the second core die and a fourth channel among the (3N+1)-th to 4N-th channels of the fourth core die input second data by receiving the write command in common and output the second data by receiving the read command in common.

9. The memory device of claim 8, wherein:
the second core die is stacked over the first core die in a stacking direction,
the third core die is stacked over the second core die in the stacking direction, and
the fourth core die is stacked over the third core die in the stacking direction.

10. The memory device of claim 9, wherein:
the first channel of the first core die and the third channel of the third core die that receive the write command in common and the read command in common are aligned in the stacking direction, and
the second channel of the second core die and the fourth channel of the fourth core die that receive the write command in common and the read command in common are aligned in the stacking direction.

11. The memory device of claim 8, wherein:
the first channel of the first core die and the third channel of the third core die that receive the write command in common and the read command in common are spaced apart from each other by the second core die, and
the second channel of the second core die and the fourth channel of the fourth core die that receive the write command in common and the read command in common are spaced apart from each other by the third core die.

12. The memory device of claim 8, further comprising a base die configured to:
output the write command in common and the read command in common to the first channel among the first to N-th channels and the third channel among the (2N+1)-th to 3N-th channels;
input the first data and output the first data through the first channel among the first to N-th channels and the third channel among the (2N+1)-th to 3N-th channels;
output the write command in common and the read command in common to the second channel among the (N+1)-th to 2N-th channels and the fourth channel among the (3N+1)-th to 4N-th channels; and
input the second data and output the second data through the second channel among the (N+1)-th to 2N-th channels and the fourth channel among the (3N+1)-th to 4N-th channels.

13. The memory device of claim 12, wherein the base die comprises:
a memory controller configured to generate the write command and the read command based on a command address, configured to generate first to fourth internal clocks by dividing a frequency of a clock, configured to generate input data from external data after the start of a write operation, and configured to generate the external data from the output data after the start of a read operation;
a first physical layer electrically connected to the first to 4N-th channels and configured to output the write command, the read command, and the first data to the first to 4N-th channels and configured to receive the first data from the first to 4N-th channels;
a second physical layer electrically connected to the first to 4N-th channels and configured to output the write command, the read command, and the second data to the first to 4N-th channels and configured to receive the second data from the first to 4N-th channels; and
a data input and output circuit configured to, in synchronization with the first to fourth internal clocks:
generate, after the start of the write operation, the first and second data from input data; and
generate, after the start of the read operation, the output data from the first and second data.

14. The memory device of claim 13, wherein the memory controller comprises:
a write read control circuit configured to generate the write command and the read command by decoding the command address;
an internal clock generation circuit configured to generate the first to fourth internal clocks by dividing the frequency of the clock; and
an error correction circuit configured to:
generate the input data by correcting an error of the external data after the start of the write operation; and
output the output data as the external data by correcting an error of the output data after the start of the read operation.

15. The memory device of claim 13, wherein the data input and output circuit comprises:
a serialization circuit configured to receive the input data in synchronization with the first to fourth internal clocks after the start of the write operation and configured to generate the first and second data by serializing the input data; and
a deserialization circuit configured to receive the first and second data in synchronization with the first to fourth internal clocks after the start of the read operation and configured to generate the output data by deserializing the first and second data.

16. A memory device comprising:
a first core die comprising first to N-th channels;
a second core die comprising (N+1)-th to 2N-th channels;
a third core die comprising (2N+1)-th to 3N-th channels; and
a fourth core die comprising (3N+1)-th to 4N-th channels,
wherein a first channel among the first to N-th channels of the first core die, a second channel among the (N+1)-th to 2N-th channels of the second core die, a third channel among the (2N+1)-th to 3N-th channels of the third core die, and a fourth channel among the (3N+1)-th to 4N-th channels of the fourth core die input and output data by sharing a write command and sharing a read command.

17. The memory device of claim 16, wherein:
the second core die is stacked over the first core die in a stacking direction,
the third core die is stacked over the second core die in the stacking direction, and
the fourth core die is stacked over the third core die in the stacking direction.

18. The memory device of claim 17, wherein the channel of the first core die, the channel of the second core die, the channel of the third core die, and the channel of the fourth core die that receive the write command in common and the read command in common are aligned in the stacking direction.

19. The memory device of claim 16, wherein:
the channel of the first core die and the channel of the second core die that receive the write command in common and the read command in common are adjacent to each other in the stacking direction,
the channel of the second core die and the channel of the third core die that receive the write command in common and the read command in common are adjacent to each other in the stacking direction, and
the channel of the third core die and the channel of the fourth core die that receive the write command and the read command in common are adjacent to each other in the stacking direction.

20. The memory device of claim 16, further comprising a base die configured to:
output the write command in common and the read command in common to at least four of the first to 4N-th channels; and
input and output the data through the at least four of the first to 4N-th channels.

21. The memory device of claim 20, wherein the base die comprises:
a memory controller configured to generate the write command and the read command based on a command address, configured to generate first to fourth internal clocks by dividing a frequency of a clock, configured to generate input data from external data after the start of a write operation, and configured to generate the external data from output data after the start of a read operation;
a first physical layer electrically connected to the first to 4N-th channels and configured to output the write command, the read command, and the data to at least four of the first to 4N-th channels and configured to receive the data from the at least four of the first to 4N-th channels;
a second physical layer electrically connected to the first to 4N-th channels and configured to output the write command, the read command, and the data to at least four of the first to 4N-th channels and configured to receive the data from the at least four of the first to 4N-th channels; and
a data input and output circuit configured to in synchronization with the first to fourth internal clocks:
generate, after the start of the write operation, the data from the input data; and
generate, after the start of the read operation, the output data from the data.

22. The memory device of claim 21, wherein the memory controller comprises:
a write read control circuit configured to generate the write command and the read command by decoding the command address;
an internal clock generation circuit configured to generate the first to fourth internal clocks by dividing the frequency of the clock; and
an error correction circuit configured to:
generate the input data by correcting an error of the external data after the start of the write operation; and
output the output data as the external data by correcting an error of the output data after the start of the read operation.

23. The memory device of claim 21, wherein the data input and output circuit comprises:
a serialization circuit configured to receive the input data in synchronization with the first to fourth internal clocks after the start of the write operation and configured to generate the data by serializing the input data; and
a deserialization circuit configured to receive the data in synchronization with the first to fourth internal clocks after the start of the read operation and configured to generate the output data by deserializing the data.

24. A memory device comprising:
a base die configured to output a write command and a read command and configured to input and output first and second data;
a first rank comprising a first core die and a second core die each comprising a plurality of channels; and
a second rank comprising a third core die and a fourth core die each comprising a plurality of channels,
wherein a first channel of the plurality of channels included in the first core die and a second channel of the plurality of channels included in the second core die input and output the first data by sharing the write command and sharing the read command, and
wherein a third channel of the plurality of channels included in the third core die and a fourth channel of the plurality of channels included in the fourth core die input and output the second data by sharing the write command and sharing the read command.

25. The memory device of claim 24, wherein the memory device is configured to independently perform a write operation and a read operation for the first rank and a write operation and a read operation for the second rank.

26. The memory device of claim 24, wherein:
in a stacking direction, the first core die is stacked over the base die, the second core die is stacked over the first core die, the third core die is stacked over the second core die, and the fourth core die is stacked over the third core die;
the first channel that shares the write command and the read command among the plurality of channels included in the first core die and the second channel that shares the write command and the read command among the plurality of channels included in the second core die are aligned in the stacking direction, and
the third channel that shares the write command and the read command among the plurality of channels included in the third core die and the fourth channel that shares the write command and the read command among the plurality of channels included in the fourth core die are aligned in the stacking direction.

27. The memory device of claim 26, wherein:
the first channel that shares the write command and the read command among the plurality of channels included in the first core die and the second channel that shares the write command and the read command among the plurality of channels included in the second core die are adjacent to each other in the stacking direction, and
the third channel that shares the write command and the read command among the plurality of channels included in the third core die and the fourth channel that shares the write command and the read command among the plurality of channels included in the fourth core die are adjacent to each other in the stacking direction.
